(19) United States
(12) Patent Application Publication
(10) Pub. No.: US 2010/0127206 A1
(43) Pub. Date: May 27, 2010

(54) Method for Forming a Nanostructure, a Nanostructure, and a Device Using the Same

(75) Inventors: Jaeyoung CHOI, Yongin-si (KR); Sang Woo KIM, Gumi-si (KR)

Correspondence Address: CANTOR COLBURN, LLP, 20 Church Street, 22nd Floor, Hartford, CT, 06103, US

(73) Assignees: SAMSUNG ELECTRONICS, CO., LTD, Suwon-si (KR); KUMOH NATIONAL INSTITUTE OF TECHNOLOGY, Gumi-si (KR)

(21) Appl. No.: 12/468,586

(22) Filed: May 19, 2009

(30) Foreign Application Priority Data
Nov. 24, 2008 (KR) 10-2008-0116956

(51) Int. Cl. H01L 41/18; C23F 1/00

(52) U.S. Cl. 252/62.9 PZ; 216/7; 252/62.9 R; 977/762

(57) ABSTRACT

A method for forming a nanostructure, a nanostructure and a device using the nanostructure, wherein hydroxide ions are provided to a surface of a nanostructure including a piezoelectric material in order to etch an outer surface of the nanostructure. In an exemplary embodiment, the nanostructure may be etched by contacting the nanostructure with a basic solution. In other exemplary embodiments the etching of the nanostructure may be performed while controlling at least one of the concentration of the basic solution, the temperature of the basic solution and the etching time. The resultant nanostructure includes a piezoelectric material and has an etched outer surface. The nanostructure may be applied to various devices.

### CROSS-REFERENCE TO RELATED APPLICATION

This application claims priority to Korean Patent Application No. 10-2008-116956 filed on Nov. 24, 2008, and all the benefits accruing therefrom under 35 U.S.C. §119, the contents of which in its entirety are herein incorporated by reference.

### BACKGROUND

1. Field

The following description relates to a method for forming a nanostructure, a nanostructure, and a device including the nanostructure.

2. Description of the Related Art

Nanomaterials have electrical, physical and chemical properties that are different from those of the corresponding bulk materials. Due to such properties, the nanomaterials may be used in the development and production of nanodevices. For example, the nanomaterials may have semiconductive or piezoelectric properties. The nanomaterials may be used in the form of nanotubes, nanorods, or the like.

Nanomaterials may be used in various devices including energy generating systems, solar cells, light emitting diodes (“LEDs”), sensors and electrochromic display devices. The quality of such devices may depend on the surface areas of the nanomaterials used therein.

### SUMMARY

In an exemplary embodiment, there is provided a method for forming a nanostructure including etching at least a portion of an outer surface of the nanostructure to provide the nanostructure with an increased surface area. In other exemplary embodiments, there are provided the nanostructure and a device using the nanostructure.

In another exemplary embodiment, there is provided a method for forming a nanostructure, wherein a plurality of hydroxide ions are contacted with an outer surface of a nanostructure containing a piezoelectric material to etch at least a portion of the outer surface of the nanostructure. In one exemplary embodiment the outer surface of the nanostructure is etched by contacting the nanostructure with a basic solution. In exemplary embodiments the etching of the nanostructure is performed while controlling at least one of the concentration of the basic solution, the temperature of the basic solution and the etching time.

In another exemplary embodiment, there is provided a nanostructure that includes a piezoelectric material wherein at least of portion of an outer surface of the nanostructure is etched. In one exemplary embodiment the nanostructure is a nanorod, a nanotube or a nanosphere. In another exemplary embodiment the nanostructure is a nanorod. In still other exemplary embodiments, the etched outer surface of the nanorod is positioned on the top surface of the nanorod, or on both the top surface and the lateral surface of the nanorod.

In still another exemplary embodiment, there is provided a device that includes a nanostructure, wherein the nanostructure has a piezoelectric material and an outer surface that is etched on at least a portion thereof.

### BRIEF DESCRIPTION OF THE DRAWINGS

The above and other aspects, advantages, and features of this disclosure will become more apparent by describing in further detail exemplary embodiments thereof with reference to the attached drawings, in which:

FIG. 1 is a perspective view illustrating an exemplary embodiment of a non-etched nanostructure;

FIG. 2 is a front view illustrating an exemplary embodiment of an etched nanostructure; and

FIG. 3 is a front view illustrating another exemplary embodiment of an etched nanostructure.

### DETAILED DESCRIPTION

The disclosure now will be described more fully hereinafter with reference to the accompanying drawings, in which embodiments are shown. This invention may, however, be embodied in many different forms and should not be construed as limited to the embodiments set forth herein. Rather, these embodiments are provided so that this disclosure will be thorough and complete, and will fully convey the concepts described herein to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the relevant art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

All methods described herein can be performed in a suitable order unless otherwise indicated herein or otherwise clearly contradicted by context. The use of any and all examples, or exemplary language (e.g., “such as”), is intended merely for illustration and does not pose a limitation on the scope of the claims. No language in the specification should be construed as indicating any non-claimed element is essential.

As used herein, the term “nanostructure” may refer to a structure having a length, thickness or diameter of several nanometers to several thousands nanometers, more specifically several nanometers to about 1,000 nanometers. There is no particular limitation in the shape of the nanostructure, and as non-limiting examples the nanostructure may have the shape of a nanotube, a nanorod, a nanosphere or the like.

In exemplary embodiments the nanostructure may be a nanorod having the form of a solid rod with a diameter (e.g., several nanometers to several thousands nanometers, more specifically several nanometers to about 1,000 nanometers) and length (e.g., several nanometers to several micrometers, more specifically several nanometers to about 1,000 nanometers).

As used herein, the term “substrate” may refer to a material on which a nanostructure may be disposed, for example a plate-like material having a substantially flat surface. The substrate may comprise at least one material. The substrate may have a multi-layer structure having a coated layer. When a catalyst layer or seed layer is formed on the substrate, the term “substrate” may include a catalyst layer or a seed layer formed on a substrate.

As used herein, a nanorod may have various characteristics including: an aspect ratio (ratio of length to diameter, i.e., length/diameter), in particular an aspect ratio of great than about 1; an angle of the nanorod to a substrate (also defined as “orientation”); a number or a weight ratio of nanorods per unit area of the substrate (also defined as “density”); a density of nanorods having a specific orientation; a uniformity in the shapes or the orientations among the nanorods (also defined as “uniformity”); or whether one nanorod stands on one contact surface between the nanorod and the substrate (including a catalyst layer or a seed layer in the case of a substrate having the catalyst layer or the seed layer).

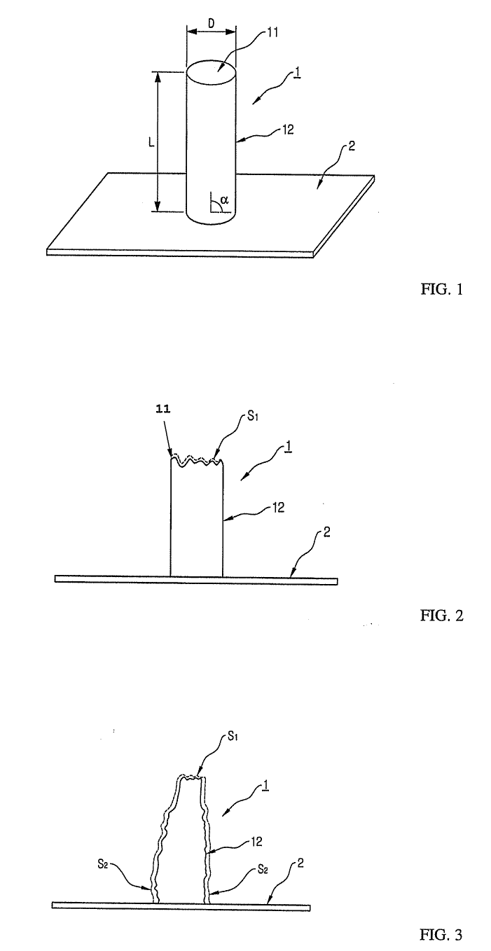

FIG. 1 is a perspective view illustrating an exemplary embodiment of a non-etched nanostructure. It will be appreciated by those skilled in the art that FIG. 1 shows a shape of a nanostructure where the shape is exaggerated for the purposes of illustration only, and therefore the shape of the nanostructure, as shown in FIG. 1, may not represent the actual shape of the nanostructure.

Referring to FIG. 1, in one exemplary embodiment the shape of the nanostructure 1 is a nanorod. The nanorod may be a solid rod having a top surface 11 and a lateral surface 12. It is to be understood that as used herein, the “top surface” of a nanorod refers to the surface that corresponds to the diameter of the nanorod. In exemplary embodiments the nanorod may have a cylindrical, a cylindroidal or a prismatic shape. The nanostructure 1 may have a shape that includes a plurality of nanorods linked to each other. It is to be understood that although FIG. 1 depicts a nanorod, in other exemplary embodiments, the nanostructure 1 may have the shape of a thin film, a nanotube, a nanosphere, or the like.

In one exemplary embodiment, the nanostructure 1 may be disposed on a substrate 2. Herein, exemplary embodiments of the nanostructure 1 may have a diameter D, a length L and an aspect ratio L/D. In one embodiment, L/D is greater than about 1. Exemplary embodiments of the nanostructure 1 may form an angle α with the substrate 2. In exemplary embodiments the substrate 2 may include a gallium nitride substrate, a glass substrate, a plastic substrate, an indium tin oxide (“ITO”) layer-coated glass substrate, or an ITO layer-coated plastic substrate. The foregoing substrates may be used alone or in any combination thereof. Although there is no particular limitation on the type of substrate 2 used, different etching conditions or methods may be used to etch the nanostructure 1 depending on the type of the substrate 2.

FIG. 2 is a front view illustrating an exemplary embodiment of an etched nanostructure 1. It will be appreciated by those skilled in the art that FIG. 2 shows the shape of a nanostructure wherein the etched portion is exaggerated for the purposes of illustration only, and therefore the shape of the nanostructure, as shown in FIG. 2, may not represent the actual shape of the etched nanostructure.

Referring to FIG. 2, in one exemplary embodiment, the outer surface of the nanostructure 1 may be an etched surface S₁. In exemplary embodiments, the outer surface of the nanostructure 1 may be a partially etched or a totally etched surface S₁. The etched surface S₁ may be a region wherein the surface of the nanostructure 1 is partially removed or indented. In one exemplary embodiment, the etched surface S₁ is a region wherein the surface of the nanostructure 1 is partially removed and indented Additionally, the etched surface S₁ may have a constant or variable depth of etching. The surface area of the nanostructure 1 may be increased due to the presence of the etched surface S₁ formed on the nanostructure 1 as compared to a non-etched nanostructure.

The etched surface S₁ may be formed by exposing the nanostructure 1 to hydroxide ions. In one exemplary embodiment, an outer surface of the nanostructure is etched by contacting the nanostructure with a basic solution. In one exemplary embodiment the nanostructure 1 may be dipped into the basic solution to perform etching of the nanostructure 1.

Exemplary embodiments of the nanostructure 1 may include a piezoelectric material having a piezoelectric effect. A piezoelectric material is a material such as crystals and certain ceramics that are generate an electric potential in response to an applied mechanical stress and vice versa. The term, “piezoelectric effect” may refer to an effect of converting electrical energy into mechanical energy and vice versa. Piezoelectricity may result from an asymmetry in the crystal structure of a piezoelectric material. For example, given three axes an a-axis, a b-axis and a c-axis in the crystal structure, piezoelectricity appears when a stronger polarity exists in the c-axis as compared to the a-axis or the b-axis.

Without being bound by theory, it is believed that, hydroxide ions such as those in a basic solution may more frequently attack (react with) a specific portion (e.g., the c-axis or the longitudinal direction) of the asymmetric crystal structure of a piezoelectric material. That is, when hydroxide ions are provided to a piezoelectric material having a stronger polarity in a specific direction, such as by contacting the piezoelectric material with a basic solution, a higher etching rate may be obtained in the specific direction having a higher polarity as compared to the etching rates in the other directions not having the stronger polarity.

In some exemplary embodiments, the concentration of the basic solution in contact with the nanostructure 1, the temperature of the basic solution, the contacting (etching) time of the nanostructure 1, or other related parameters may be controlled to perform selective etching of the surface of the nanostructure 1. In addition, any combination of the foregoing parameters may be controlled to perform selective etching of the surface of the nanostructure 1. The term “selective etching” refers to etching that occurs in a specific direction of a single nanorod or other nanostructure and that includes a piezoelectric material.

Referring to FIGS. 1 and 2, the etched surface S₁ of the nanostructure 1 may be formed by etching the top surface 11 of the nanostructure 1. This is because the etching may occur relatively more vigorously along a specific direction D1 having a higher polarity than the other directions in the crystal structure of the piezoelectric material forming the nanostructure 1. Therefore, only the top surface 11 of the nanostructure may be selectively etched by suitably controlling the etching conditions (e.g., the concentration of the basic solution, the temperature of the basic solution, the etching time of the nanostructure 1, or the like). Due to the presence of an etched surface S1, the nanostructure 1 may have an increased surface area.

FIG. 3 is a front view illustrating an exemplary embodiment of an etched nanostructure 1. It will be appreciated by those skilled in the art that FIG. 3 shows the shape of a nanostructure, wherein the etched portion is exaggerated for the purposes of illustration only, and therefore the shape of the nanostructure, as shown in FIG. 3, may not represent the actual shape of the etched nanostructure.

Referring to FIGS. 1 and 3, etching may not only occur in the specific direction D1, which has a higher polarity than the other directions of the piezoelectric material, but etching may also occur in the other directions of the piezoelectric material that forms the nanostructure 1. The other directions of the piezoelectric material may be etched by suitably controlling the etching conditions of the nanostructure 1.

Therefore, in one exemplary embodiment, the nanostructure 1 may have an additional etched surface S₂ located on the lateral surface 12 of the nanostructure 1. The additional etched surface S₂ is in addition to the etched surface S₁ located on the top surface 11 of the nanostructure 1. Like the etched surface S₁ on the top surface 11, the etched surface S₂ on the lateral surface 12 may be formed by partially removing and indenting the surface of the nanostructure 1. Additionally, the etched surface S₂ may have a constant or a variable depth of etching.

In exemplary embodiments, the above-described nanostructure 1 may be applied to various devices. In exemplary embodiments the device is selected from the group consisting of energy generating systems, solar cells, light emitting diodes (“LEDs”), sensors, and electrochromic display devices. Since the nanostructure 1 may have an increased surface area due to the presence of etching, the nanostructure 1 may be used in various devices including energy generating systems, solar cells, LEDs, and electrochromic display devices to improve the efficiency of the devices. Further, in one exemplary embodiment the nanostructure 1 may be used in sensors to impart an improved sensitivity to the sensors.

Hereinafter, a method for growing nanostructures will be explained in detail. A nanostructure having an increased surface area may then be obtained by etching such grown nanostructures according to an exemplary embodiment.

An exemplary embodiment of a method for forming a nanostructure includes growing a nanorod on a substrate. It will be appreciated by those skilled in the art that different methods may be used to grow the nanorod, and the specific shape or method disclosed herein are not intended to limit the scope of the disclosure.

In one exemplary embodiment, the methods for forming the nanorods include a liquid phase process, a vapor phase process, a vapor-liquid phase growing process, a template process and other similar methods, which can be used alone or in combination. The liquid phase process, the vapor phase process and the vapor-liquid phase growing process may include growing nanorods on a substrate using nanoseeds in combination with liquid or vapor reaction sources. The template process may include forming a patterned catalyst on a substrate to provide a catalyst template, and then forming the nanorods such that the nanorods have the pattern by using liquid or vapor reaction sources.

Hereinafter, as a non-limiting example, a method for growing the nanorods including zinc oxide will be explained in further detail.

For reference, zinc oxide is a group IIB-VIA compound semiconductor of direct transition type having a wide band gap of about 3.37 electron volts (eV) at room temperature. The crystal structure of zinc oxide is classified as either a hexagonal wurtzite crystal structure or a cubic zinc-blende crystal structure. Among these structures, zinc oxide having the hexagonal wurtzite crystal structure exhibits piezoelectricity. The wurtzite crystal structure is an asymmetric crystal structure.

Zinc oxide further has a relatively short distance between ions in the c-axis as compared to the distances between ions in the other axes. Due to this characteristic, zinc oxide has an effective ionic charge ratio of about 1:1.2 and shows a relatively high polarity in the direction of the c-axis, thereby resulting in piezoelectricity.

In an example of the liquid phase process, a layer of a material (e.g., zinc acetate), which enables the seed growth of zinc oxide, is formed on a substrate in a small amount and at a uniform thickness using a spin coating process, a dip coating process or another coating process. The substrate is then heated (e.g., to a temperature of about 100 degrees Celsius (° C.) or lower) and dried to form the nanoseeds. The nanoseeds are disposed on the substrate as a uniform layer also known as a seed layer. The substrate having the seed layer may be introduced into an aqueous solution having a basic pH (e.g., pH of about 10) and containing a zinc salt, such as zinc nitrate, zinc sulfate, zinc chloride or zinc acetate, and aqueous ammonia and heated (e.g., to a temperature of about 100° C. or lower) to grow nanorods.

The basic pH (e.g., about pH 10) is suitable for the growth of the zinc oxide nanorods. The aqueous ammonia together with the zinc salt may be used to produce an aqueous basic solution having a pH of about 10. The aqueous ammonia also contributes to the growth of the nanorods.

For reference, the above-described process for forming the nanorods may be represented by the following Reaction Scheme 1:

NH₃+H₂O [symbol] NH₄⁺+OH⁻

Zn₂+2OII⁻→ZnO+II₂O

Zn₂⁺4NH₃ [symbol] Zn(NH₃)₄²⁺

Zn(NH₃)₄²⁺+2OH⁻→ZnO+4NH₃+H₂O Reaction Scheme 1

As the size of the nanoseeds increases, the nanorods grown therefrom may have a larger diameter or length. Additionally, a higher growth temperature, a longer growth time, or a greater amount or a higher concentration of the zinc salt in the reaction source (i.e., the zinc salt solution) may also provide an increased diameter or length to the nanorods. Further, a higher growth temperature, a longer growth time, or a greater amount or higher concentration of the zinc salt in the reaction source (i.e., the zinc salt solution) may provide a larger aspect ratio when the diameter and the length of the nanorods increase and the growth of the nanorods occurs strongly in the direction of the c-axis.

In one exemplary embodiment the substrate may have a regular crystal structure to prevent the random growth of the nanorods, such as the growth of a plurality of nanorods from one contact surface. A substrate having a regular crystal structure also makes it possible to control the orientation of the nanorods. Additionally, in one exemplary embodiment the substrate or the seed layer may have a decreased surface roughness in order to planarize the contact surface between the nanorods and the substrate or seed layer at the location where the nanorods start to grow.

In exemplary embodiments as the density of the seed layer increases, the nanorods grown from the seed layer will also have a higher density. Additionally, in exemplary embodiments a uniform seed size may also improve the uniformity of the structure of the nanorods.

In an example of the vapor phase process, a reaction source, such as zinc or a zinc oxide/graphite mixed powder, is loaded into the reaction furnace of a thermal chemical vapor deposition system. A substrate is provided on which a catalyst (e.g., a catalyst metal such as gold (Au), cobalt (Co) or copper (Cu)) is deposited. The reaction source is heated on the substrate at a high temperature (e.g., about 700 to about 1200° C.) to allow the catalyst and the zinc gas to react with each other in order to grow the nanorods. In one exemplary embodiment, a carrier gas may be used to transfer the reaction source. The carrier gas may include argon (Ar), nitrogen (N₂), combinations thereof, or other similar gases.

In an exemplary embodiment of the vapor phase process, the crystal structure, the surface roughness of the substrate or the surface roughness of the catalyst layer deposited on the substrate may be controlled to prevent the random growth of and to control the orientation of the nanorods. The uniformity or density of the nanorods may be controlled by adjusting the amount or density of the catalyst metal, size of the catalyst particle, growth temperature, growth time, and the like. Also, in one exemplary embodiment the diameter and/or the length (and thus the aspect ratio) of the nanorods may be controlled by adjusting the growth temperature, the growth time or a combination thereof. Since a carrier gas transfers the reaction source during the vapor phase process, the aspect ratio, the orientation of and the uniformity of the nanorods may be controlled by adjusting the flow rate of the carrier gas.

In one exemplary embodiment a vapor-liquid phase process is used for growing nanorods. In another exemplary embodiment the vapor-liquid phase process is spray pyrolysis. In the vapor-liquid phase process, water-soluble materials (e.g., zinc acetate, zinc chloride, etc.) may be used as the reaction source. The reaction source is dissolved in deionized water to be ionized. Then, ultrasonic pyrolysis is performed to spray the reaction source. The reaction source is then transferred to the substrate by a carrier gas (e.g., Ar or N₂) to form the nanorods on the substrate under an oxygen atmosphere at a temperature of about 400° C. or higher.

Like the above-mentioned processes, in the vapor-liquid phase process, the crystal structure or the surface roughness of the substrate may be controlled to prevent random growth or to control the orientation of the nanorods. Also, the aspect ratio of the nanorods may be controlled by adjusting the growth time or growth temperature.

An exemplary embodiment of the template process may include a process for forming the zinc oxide nanorods using an anodic aluminum oxide (“AAO”) template.

In one exemplary embodiment the aluminum surface may be planarized by electropolishing a bulk aluminum to form an AAO template having a high alignment degree of regularly arranged pores. Next, an acid solution (e.g., oxalic acid) may be used to perform a primary anodization of the aluminum surface. Then, the resultant AAO layer is subjected to wet etching using an acid solution (e.g., mixed solution of chromic acid and phosphoric acid), followed by a secondary anodization under the same conditions to form an AAO nanotemplate having regularly arranged pores. In addition, a reaction source such as a water soluble zinc source (e.g., zinc chloride, zinc acetate, etc.), is dissolved to be used as an electrolyte. Finally, the pores of the AAO nanotemplate are filled by electroplating and the template is removed to form the nanorods.

In the template method, in addition to adjusting the reaction source, the growth temperature, the growth time, etc., the alignment degree of a template such as an AAO template may be adjusted to control the density, the aspect ratio and the uniformity of the nanorods.

The above-mentioned methods and other suitable methods may be used to provide the nanorods. In some exemplary embodiment the nanorods may be obtained through a low-temperature process (e.g., a liquid phase process carried out at about 100° C. or lower or at about 90° C. or lower). Such a low-temperature process may partially or totally avoid the formation of defects in the substrate, which may occur in the case of a high-temperature process. Therefore, the low-temperature process may avoid limitations in the use of a substrate, and facilitate the process for forming the nanorods.

Hereinafter, description will now be made with reference to an exemplary embodiment of a method for forming a nanostructure by etching the nanorods grown, for example, as described above.

The nanorods grown, for example by the methods as described above may be etched by providing hydroxide ions to the nanorods, that is, by contacting an outer surface of the nanorod with a plurality of hydroxide ions. In exemplary embodiments the nanorods may be etched by either dipping or immersing the nanorods into a vessel (e.g., a water tank) containing a basic solution such that they are in contact with the basic solution. In one embodiment, when the nanorods are to be used in devices, the outer surfaces of the nanorods that are to be in contact with other materials in the devices may be etched by the hydroxide ions.

As described above, the nanorods may include a piezoelectric material. Examples of the piezoelectric material include but are not limited to aluminum orthophosphate (AlPO₄), quartz, Rochelle salt, topaz, gallium orthophosphate (GaPO₄), lanthanum gallium silicate (La₃Ga₅SiO₁₄), barium titanate (BaTiO₃), bismuth titanate (Bi₄Ti₃O₁₂), lead titanate (PbTiO₃), zinc oxide (ZnO), zirconium lead titanate (“PZT”; Pb[Zr_{X}T_{1-X}]O₃, 0<x<1), lanthanum bismuth titanate (“BLT”; [Bi_{4-X}La_{X}]Ti₃O₁₂0<x<1), tin oxide (SnO₂), potassium niobate (KNbO₃), lithium niobate (LiNbO₃), lithium tantalate (LiTaO₃), sodium tungstate (Na₂WO₃), sodium barium niobate (Ba₂NaNb₅O₅), potassium lead niobate (Pb₂KNb₅O₁₅), sodium potassium niobate (KNaNb₅O₅), bismuth ferrite (BiFeO₃), or the like.

For reference, barium titanate (BaTiO₃) has a three-dimensional symmetric cubic structure at a temperature of about 130° C. or higher (a=b=c=4.009 angstroms (Å) at about 130° C.). A shift from the cubic structure to an asymmetric tetragonal structure (extension in the direction of the c-axis) occurs below a temperature of about 130° C. The extension of the structure occurs in the direction of the c-axis to form the asymmetric tetragonal structure and the c-axis length increases relative to a temperature drop thereby resulting in piezoelectricity.

Any basic solutions capable of generating hydroxide ions may be used as the basic solution. Strongly basic or weakly basic solutions may be used. Inorganic basic solutions or organic basic solutions may be used. In one exemplary embodiment the basic solution may include, but is not limited to lithium hydroxide, sodium hydroxide, potassium hydroxide, rubidium hydroxide, cesium hydroxide, francium hydroxide, barium hydroxide, strontium hydroxide, calcium hydroxide, copper hydroxide, iron hydroxide, ammonium hydroxide, tetramethylammonium hydroxide, tetrabutylammonium hydroxide, choline hydroxide, alanine, phosphazene, histidine, imidazole, benzimidazole, purine, pyridine, pyrimidine, methylamine, or the like. The foregoing basic solutions may be used alone or in any combination thereof. In one exemplary embodiment the basic solution may be an aqueous basic solution.

In one exemplary embodiment, when the nanorod includes zinc oxide and the basic solution is an aqueous solution, the etching reaction may be represented by the following

Reaction Scheme 2:

ZnO+H₂O+2OH⁻→Zn(OH)₄²⁻

Zn(OH)₄²→Zn²⁺+4OH⁻ Reaction Scheme 2

As described above, the nanorod that includes a piezoelectric material may provide a higher etching rate in a specific direction (e.g., in the c-axis or the longitudinal direction) as compared to the other axes or directions. Therefore, the nanorod may be selectively etched by controlling the etching conditions. For example, at least one etching process parameter selected from the group consisting of the concentration of the basic solution, the temperature of the basic solution and the etching time may be controlled to perform selective etching of the nanorod.

In an exemplary embodiment, the nanorod that includes zinc oxide may be etched by using an aqueous potassium hydroxide (KOH) solution to contact the outer surface of a nanostructure, e.g., a nanorod.

For example, the nanorod may be etched by using an aqueous potassium hydroxide (KOH) solution having a concentration of about 0.05 to about 0.1 molar (M) at a temperature of about 30 to about 80° C. The nanorod may be etched for about 0.5 to about 48 hours. In this exemplary embodiment, since the aqueous potassium hydroxide (KOH) solution has a relatively low temperature and a relatively low concentration, selective etching may be accomplished on the top surface 11 (see FIG. 2) of the nanorod, which shows a relatively higher etching rate.

On the other hand, the nanorod may be etched by using an aqueous potassium hydroxide (KOH) solution having a concentration of about 0.3 to about 0.35 M at a temperature of about 40 to about 100° C. The nanorod may be etched for about 0.5 to about 2 hours. In this case, since the aqueous potassium hydroxide (KOH) solution has a relatively high temperature and relatively high concentration, the nanorod may be etched not only on the top surface 11 (see FIG. 1) of the nanorod but also on the lateral surface 12 (see FIG. 3) thereof. As a result, the nanorod may have an increased surface area in all directions.

In another exemplary embodiment, a nanorod that includes zinc oxide may be etched by using an aqueous ammonia (NH₃) solution.

For example, the nanorod may be etched by using an aqueous ammonia (NH₃) solution having a concentration of about 0.02 to about 0.1 millimolar (mM). In one exemplary embodiment, the aqueous NH₃ solution may be at room temperature. The nanorod may be etched for about 5 to about 60 minutes. In this case, since the aqueous NH₃ solution has a relatively low temperature and relatively low concentration, selective etching may be accomplished on the top surface 11 (see FIG. 2) of the nanorod, which shows a relatively higher etching rate.

On the other hand, the nanorod may be etched by using an aqueous NH₃ solution having a concentration of about 0.2 to about 0.5 mM. The aqueous NH₃ solution may be at a temperature from about room temperature to about 50° C. The nanorod may be etched for about 5 to about 40 minutes. In this exemplary embodiment, since the aqueous NH₃ solution has a relatively high temperature and relatively high concentration, the nanorod may be etched not only on the top surface 11 (see FIG. 1) of the nanorod but also on the lateral surface 12 (see FIG. 3) thereof. As a result, the nanorod may have an increased surface area.

When the concentration of the basic solution, temperature of the basic solution, or etching time of the nanorod is increased continuously, the nanorod may be completely etched and removed from the substrate. Therefore, the concentration of the basic solution, temperature of the basic solution or etching time of the nanorod may be controlled such that only the outer surface of the nanorod is etched.

Furthermore, the concentration of the basic solution, the temperature of the basic solution or the etching time of the nanorod may be varied depending on the type of the piezoelectric material, the type of the basic solution and the substrate used for forming the nanorod. In one exemplary embodiment, the above conditions may be controlled while monitoring the nanorod, for example, with a scanning electron microscopy (“SEM”) photograph taken during the etching process.

In one exemplary embodiment, the etching using a basic solution may be performed at a low temperature of about 100° C. or lower. Such a low-temperature etching process accomplishes selective etching. In addition, the low-temperature etching process may be combined with any of the above-mentioned low-temperature processes used for forming the nanorods. This results in an overall low-temperature process, which is used for both forming and etching the nanorods. Such an overall low-temperature process may prevent damage to or defects in or on a substrate. Therefore, there is no particular limitation on the type of substrate. In one exemplary embodiment, a gallium nitride substrate, a glass substrate, a plastic substrate, an ITO layer-coated glass substrate or an ITO layer-coated plastic substrate may be used alone or in any combination of the foregoing.

Methods for etching the nanostructure are not limited to the above methods, which use a basic solution. The nanostructure may be etched by using any material that is capable of providing hydroxide ions. In exemplary embodiments the nanostructure may be etched by using a gaseous material or ion through a wet etching process, a dry etching process or another suitable etching process.

While the exemplary embodiments have been shown and described, it will be understood by those skilled in the art that various changes in form and details may be made thereto without departing from the spirit and scope of the present invention as defined by the appended claims.

In addition, many modifications can be made to adapt a particular situation or material to the teachings of the invention without departing from the essential scope thereof. Therefore, it is intended that the present invention not be limited to the particular exemplary embodiments disclosed as the best mode contemplated for carrying out this invention, but that the present invention will include all embodiments falling within the scope of the appended claims.

What is claimed is:

1. A method for forming a nanostructure, comprising:
contacting a plurality of hydroxide ions and an outer surface of a nanostructure comprising a piezoelectric material, to etch at least a portion of the outer surface of the nanostructure.

2. A method for forming a nanostructure according to claim 1, wherein the nanostructure is etched by contacting the outer surface of the nanostructure with a basic solution.

3. A method for forming a nanostructure according to claim 2, wherein the contacting is performed while controlling at least one selected from the group consisting of a concentration of the basic solution, a temperature of the basic solution and a contacting time.

4. A method for forming a nanostructure according to claim 1, wherein the contacting is performed at a temperature of about 100° C. or lower.

5. A method for forming a nanostructure according to claim 2, wherein the nanostructure is a nanorod, and the method further comprises
providing a nanorod comprising the piezoelectric material on a substrate; and
contacting an outer surface of the nanorod with the basic solution to etch at least a portion the surface of the nanorod.

6. A method for forming a nanostructure according to claim 5, wherein the substrate is at least one selected from the group consisting of a gallium nitride substrate, a glass substrate, a plastic substrate, an indium tin oxide layer-coated glass substrate, an indium tin oxide layer-coated plastic substrate and a combination thereof.

7. A method for forming a nanostructure according to claim 2, wherein the basic solution comprises at least one selected from the group consisting of lithium hydroxide, sodium hydroxide, potassium hydroxide, rubidium hydroxide, cesium hydroxide, francium hydroxide, barium hydroxide, strontium hydroxide, calcium hydroxide, copper hydroxide, iron hydroxide, ammonium hydroxide, tetramethylammonium hydroxide, tetrabutylammonium hydroxide, choline hydroxide, alanine, phosphazene, histidine, imidazole, benzimidazole, purine, pyridine, pyrimidine, methylamine and a combination thereof.

8. A method for forming a nanostructure according to claim 2, wherein:
the piezoelectric material comprises zinc oxide and the basic solution is an aqueous solution comprising potassium hydroxide;
the aqueous potassium hydroxide solution has a molar concentration of about 0.05 to about 0.1 M and a temperature of about 30 to about 80° C.; and
the nanostructure is contacted with the basic solution for about 0.5 to about 48 hours.

9. A method for forming a nanostructure according to claim 2, wherein:
the piezoelectric material comprises zinc oxide and the basic solution is an aqueous solution comprising potassium hydroxide;
the aqueous potassium hydroxide solution has a molar concentration of about 0.3 to about 0.35 M and a temperature of about 40 to about 100° C.; and
the nanostructure is contacted with the basic solution for about 0.5 to about 2 hours.

10. A method for forming a nanostructure according to claim 2, wherein:
the piezoelectric material comprises zinc oxide and the basic solution is an aqueous solution comprising ammonia;
the aqueous ammonia solution has a molar concentration of about 0.02 to about 0.1 mM; and
the nanostructure is contacted with the basic solution for about 5 to about 60 minutes.

11. A method for forming a nanostructure according to claim 2, wherein:
the piezoelectric material comprises zinc oxide and the basic solution is an aqueous solution comprising ammonia;
the aqueous ammonia solution has a molar concentration of about 0.2 to about 0.5 mM and a temperature of about 50° C. or lower;
and the nanostructure is contacted with the basic solution for about 5 to about 40 minutes.

12. A method for forming a nanostructure according to claim 1, wherein the piezoelectric material is selected from the group consisting of aluminum orthophosphate, quartz, Rochelle salt, topaz, gallium orthophosphate, lanthanum gallium silicate, barium titanate, bismuth titanate, lead titanate, zinc oxide, zirconium lead titanate, lanthanum bismuth titanate, tin oxide, potassium niobate, lithium niobate, lithium tantalate, sodium tungstate, sodium barium niobate, potassium lead niobate, sodium potassium niobate and bismuth ferrite.

13. A nanostructure comprising a piezoelectric material, wherein at least a portion of the nanostructure has an etched outer surface.

14. A nanostructure according to claim 13, wherein the nanostructure is a nanorod.

15. A nanostructure according to claim 14, wherein the etched outer surface is on a top surface of the nanorod.

16. A nanostructure according to claim 15, wherein the etched outer surface is on a top surface and on a lateral surface of the nanorod.

17. A nanostructure according to claim 14, wherein the piezoelectric material is selected from the group consisting of aluminum orthophosphate, quartz, Rochelle salt, topaz, gallium orthophosphate, lanthanum gallium silicate, barium titanate, bismuth titanate, lead titanate, zinc oxide, zirconium lead titanate, lanthanum bismuth titanate, tin oxide, potassium niobate, lithium niobate, lithium tantalate, sodium tungstate, sodium barium niobate, potassium lead niobate, sodium potassium niobate and bismuth ferrite.

18. A device comprising a nanostructure, wherein the nanostructure comprises a piezoelectric material and wherein the nanostructure has an etched outer surface.

19. The device of claim 18 wherein the device is selected from the group consisting of an energy generating system, a solar cell, a light emitting diode, a sensor and an electrochromic display device.
